(19) United States
(12) Patent Application Publication
(10) Pub. No.: US 2025/0199402 A1
(43) Pub. Date: Jun. 19, 2025

(54) POSITIVE PHOTOSENSITIVE RESIN COMPOSITION, CURED PRODUCT OF THE SAME, AND DISPLAY DEVICE INCLUDING THE SAME

(71) Applicant: TORAY INDUSTRIES, INC., Tokyo (JP)

(72) Inventors: Susumu TANAKA, Otsu-shi, Shiga (JP); Tomoyuki YUBA, Otsu-shi, Shiga (JP); Mitsuhito SUWA, Otsu-shi, Shiga (JP)

(73) Assignee: TORAY INDUSTRIES, INC., Tokyo (JP)

(21) Appl. No.: 18/843,313

(22) PCT Filed: Mar. 1, 2023
(86) PCT No.: PCT/JP2023/007540

§ 371 Date: Sep. 3, 2024

(30) Foreign Application Priority Data
Mar. 25, 2022 (JP) 2022-049582

(51) Int. Cl. G03F 7/008; G03F 7/039

(52) U.S. Cl. CPC G03F 7/008; G03F 7/0392

(57) ABSTRACT

A positive photosensitive resin composition may include (a) polysiloxane, and (b) a naphthoquinone diazide compound represented by formula (1):

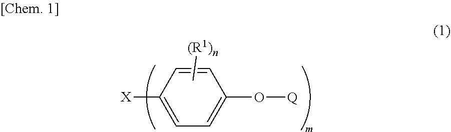

(in the formula (1), R¹ is an alkyl group having 1 to 8 carbon atoms; Q is a naphthoquinone diazide sulfonyl group represented by the structure shown below or a hydrogen atom, and at least one of all Qs in the formula (1) is a naphthoquinone diazide sulfonyl group: n is an integer of 0 to 4; m is an integer of 4 to 8; and X is a tetravalent to octavalent organic group having 4 to 30 carbon atoms)

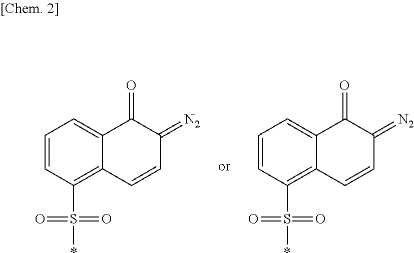

(in the above structure, * represents a binding site).

### TECHNICAL FIELD

The present invention relates to a photosensitive composition that can be suitably used for planarization films for thin film transistor (TFT) substrate of liquid crystal display devices, OLED display devices, and the like, and inter-layer dielectric films, a cured product formed from the composition, and a display device including the cured product.

### BACKGROUND ART

In recent years, a method of increasing an aperture ratio of the display device is known as a method of achieving still higher definition and higher resolution in liquid crystal displays or OLED displays (see Patent Literature 1). This is a method of increasing the aperture ratio compared to the conventional technology, by providing a transparent planarization film as a protective film on the top of the TFT substrate, making it possible to overlap the data lines with the pixel electrode.

As a material for such a planarization film for TFT substrate, which needs to have characteristics of high thermal resistance and high transparency and to form a via hole pattern of about several micrometers in order to secure conductivity between the TFT substrate electrode and the ITO electrode, a material having positive photosensitivity is generally used. As a representative material, a material combining an acrylic resin and a naphthoquinone diazide compound (hereinafter, also referred to as NQD) is known (see Patent Literatures 2 to 4), but such a material has insufficient thermal resistance and has a problem of its cured product strongly coloring upon high-temperature processing of the substrate.

Also, a positive type material using polyimide is known as a material having high thermal resistance (see Patent Literature 5). However, such a material does not have a sufficient level of transparency due to high light absorption in the polymer, and there is a room for improvement in sensitivity as well.

On the other hand, polysiloxane is known as another material having characteristics of high thermal resistance and high transparency, and a material combining polysiloxane with NQD in order to impart positive photosensitivity is known (see Patent Literatures 6 and 7). These materials have high transparency, and the transparency does not decrease even when the substrate is subjected to high-temperature processing, and a cured product having high transparency can be obtained.

In recent years, there has been a demand for increasing sensitivity of the positive photosensitive composition used as a material, in order to improve throughput of the production of the liquid crystal displays and OLED displays. The photosensitive system using naphthoquinone diazide described above develops an ability to reduce alkali solubility (dissolution inhibition) of the composition by adding the NQD-based photosensitizer, providing resistance of the unexposed portion for a developer. On the other hand, in the exposed portion, naphthoquinone diazide is converted into indene carboxylic acid, which increases solubility in the developer. Patterning is performed using the solubility difference between the exposed portion and the unexposed portion in the alkaline developer. In order to obtain patterning performance of high sensitivity and high residual film thickness ratio, it is most absolutely essential to select a photosensitizer that can sufficiently secure the difference in solubility between them. That is, in the unexposed portion, sufficient dissolution inhibition effect is performed against the alkaline developer due to the interaction between the photosensitizer and the resin. On the other hand, in the exposed portion, a highly sensitive photosensitizer that can efficiently decompose with a slight light and develop sufficient alkali solubility should be used.

In order to solve this problem, photosensitizers in which the hydroxyl group of the hydroxybenzophenone-based or bisphenol-based compound is esterified with naphthoquinone diazide sulfonate halide, etc. have been investigated (see Patent Literatures 8 and 9). When siloxane materials are combined with these photosensitizers, alkali dissolution inhibition ability of the composition is performed, resulting in larger difference in solubility between the unexposed portion and the exposed portion, and thus higher sensitivity can be expected, compared to other materials. However, the demands for high sensitivity, aiming at increasing size of the substrates used for production of the recent liquid crystal displays and OLED displays and reducing production cost, have yet to meet.

In addition, polysiloxane has a problem in that unbalanced equilibrium reactions of condensation between Si—OH groups or cleavage of Si—O—Si bond changes the molecular weight of the polymer and affects the storage stability of the composition, due to its characteristics as a material.

That is, a photosensitizer that has excellent dissolution inhibition ability of the unexposed portion and also improves the storage stability of polysiloxane is required for the positive photosensitive material containing polysiloxane.

### CITATION LIST

### Patent Literature

Patent Literature 1: JP-H9-152625A
Patent Literature 2: JP 2001-281853A
Patent Literature 3: JP-H5-165214A
Patent Literature 4: JP 2002-341521A
Patent Literature 5: JP 2001-5179A
Patent Literature 6: JP 2006-178436A
Patent Literature 7: JP 2009-211033A
Patent Literature 8: JP-S64-6947A
Patent Literature 9: JP-H3-20743A

### SUMMARY OF INVENTION

### Technical Problem

The present invention has been made based on the above-mentioned circumstances, and provides a positive photosensitive composition having patterning performance of high sensitivity and high residual film thickness ratio together with high storage stability.

Further, another object of the present invention is to provide a cured product that can be used for a planarization film for TFT substrate, an inter-layer dielectric film, a core or clad material, which is formed from the photosensitive composition described above, and devices including the cured product, such as display devices, semiconductor devices, and optical waveguides.

### Solution to Problem

That is, the present invention is a positive photosensitive resin composition including: (a) polysiloxane, and (b) a naphthoquinone diazide compound represented by formula (1):

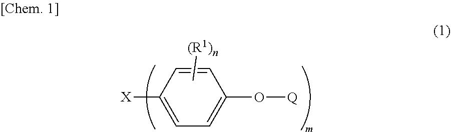

(in the formula, R¹ is an alkyl group having 1 to 8 carbon atoms; Q is a naphthoquinone diazide sulfonyl group represented by the structure shown below or a hydrogen atom, and at least one of all Qs in the formula (1) is a naphthoquinone diazide sulfonyl group: n is an integer of 0 to 4; m is an integer of 4 to 8; and X is a tetravalent to octavalent organic group having 4 to 30 carbon atoms)

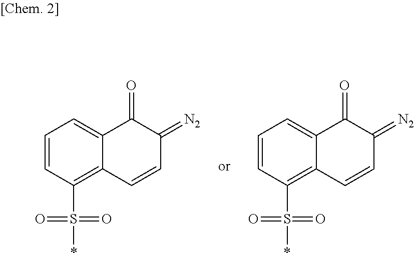

(in the above structure, * represents a binding site).

### Advantageous Effects of Invention

The positive photosensitive resin composition of the present invention has patterning performance with high sensitivity and high residual film thickness ratio, and also has high storage stability.

### DESCRIPTION OF EMBODIMENTS

The present invention relates to a positive photosensitive resin composition including (a) polysiloxane (hereinafter also referred to as “component (a)”), and (b) a naphthoquinone diazide compound represented by formula (1) (hereinafter also referred to as “component (b)”):

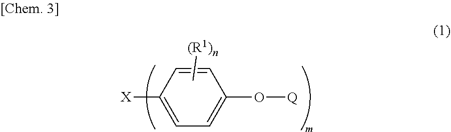

(in the formula (1), R¹ is an alkyl group having 1 to 8 carbon atoms; Q is a naphthoquinone diazide sulfonyl group represented by the structure shown below or a hydrogen atom, and at least one of all Qs in the formula (1) is a naphthoquinone diazide sulfonyl group: n is an integer of 0 to 4; m is an integer of 4 to 8; and X is a tetravalent to octavalent organic group having 4 to 30 carbon atoms).

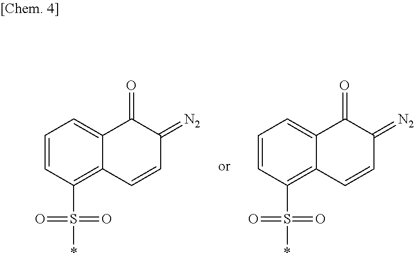

(in the above structure, * represents a binding site).

The positive photosensitive resin composition including the component (b) has positive photosensitivity so that the exposed portion is removed by a developer. Further, interaction between the component (b) and the component (a) exerts a dissolution inhibition effect in the unexposed portion.

The photosensitive composition of the present invention includes (a) polysiloxane. As the component (a), a known one can be used.

Specific examples of (a) polysiloxane include the one having one or more repeating structural units selected from the group consisting of repeating structural units represented by formula (2) to formula (7). Such a structure is incorporated in the polymer structure by mixing and reacting one or more silanes represented by formula (8).

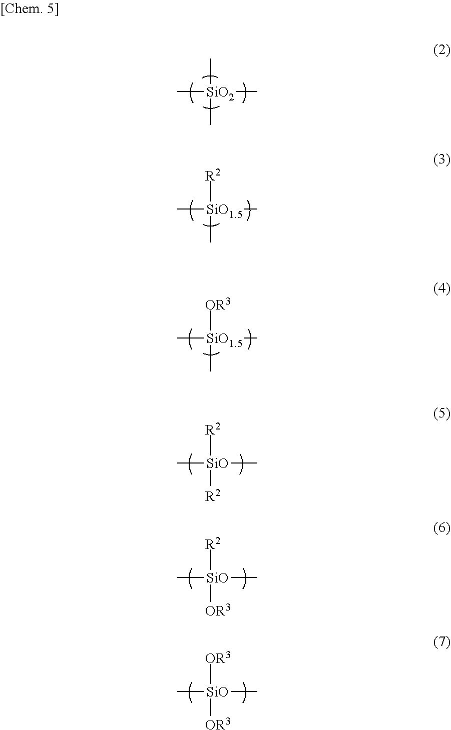

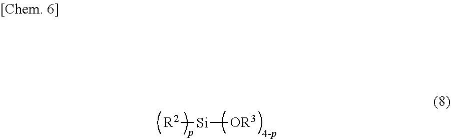

Each R² is independently any one of a hydrogen atom, a monovalent saturated aliphatic group having 1 to 10 carbon atoms, a monovalent unsaturated aliphatic group having 2 to 10 carbon atoms, or an aryl group having 6 to 15 carbon atoms. Each R³ is independently any one of a hydrogen atom, an alkyl group having 1 to 6 carbon atoms, an acyl group having 1 to 6 carbon atoms, or an aryl group having 6 to 15 carbon atoms. p is an integer of 0 to 2.

All of the monovalent saturated aliphatic group having 1 to 10 carbon atoms, monovalent unsaturated aliphatic group having 2 to 10 carbon atoms, and aryl group having 6 to 15 carbon atoms, exemplified as R² in the formula (8), may be substituted, or may be unsubstituted and have no substituent. In a case of the monovalent saturated aliphatic group or the monovalent unsaturated aliphatic group, an ether group, a thioether group, an ester group, an amide group, or the like may be inserted in the structure, which can be selected according to the characteristics of the composition.

Specific examples of the monovalent saturated aliphatic group having 1 to 10 carbon atoms include a methyl group, an ethyl group, an n-propyl group, an isopropyl group, an n-butyl group, a t-butyl group, an n-hexyl group, an n-decyl group, a trifluoromethyl group, a 2,2,2-trifluoroethyl group, a 3,3,3-trifluoropropyl group, a 3-glycidoxypropyl group, a 2-(3,4-epoxycyclohexyl)ethyl group, a (3-alkyloxetane-3-yl) methoxyalkyl group, an aminopropyl group, a 3-mercaptopropyl group, and a 3-isocyanatepropyl group.

Specific examples of the monovalent unsaturated aliphatic group having 2 to 10 carbon atoms include a vinyl group, a 3-acryloxypropyl group, and a 3-methacryloxypropyl group.

Specific examples of the aryl group having 6 to 15 carbon atoms include a phenyl group, a tolyl group, a p-styryl group, a p-methoxyphenyl group, a p-hydroxyphenyl group, a 1-(p-hydroxyphenyl)ethyl group, a 2-(p-hydroxyphenyl)ethyl group, a 4-hydroxy-5-(p-hydroxyphenylcarbonyloxy)pentyl group, and a naphthyl group.

Both of the alkyl group and the acyl group exemplified as R³ of the formula (8) may be substituted, or may be unsubstituted and have no substituent, and can be selected according to the characteristics of the composition. Specific examples of the alkyl group include a methyl group, an ethyl group, an n-propyl group, an isopropyl group, and an n-butyl group. A specific example of the acyl group is acetyl group. A specific example of the aryl group is a phenyl group.
p in the formula (8) is an integer of 0 to 2. The formula (8) represents a tetrafunctional silane when p=0, a trifunctional silane when p=1, and a bifunctional silane when p=2.

Specific examples of the silane that can be used for synthesis of the component (a) include tetrafunctional silane such as tetramethoxysilane, tetraethoxysilane, tetraacetoxysilane, and tetraphenoxysilane; trifunctional silane such as methyltrimethoxysilane, methyltriethoxysilane, methyltriisopropoxysilane, methyltri-n-butoxysilane, ethyl trimethoxysilane, ethyl triethoxysilane, ethyl triisopropoxysilane, ethyl tri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, phenyltrimethoxysilane, phenyltriethoxysilane, p-hydroxyphenyltrimethoxysilane, 1-(p-hydroxyphenyl)ethyl trimethoxysilane, 2-(p-hydroxyphenyl)ethyl trimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyl trimethoxysilane, (3-ethyl-3-((3-(trimethoxysilyl)propoxy)methyl)oxetane), (oxetane-3-yl)methyltrimethoxysilane, (oxetane-3-yl)methyltriethoxysilane, (oxetane-3-yl)methyltriacetoxysilane, 3-mercaptopropyltrimethoxysilane, phenyltrimethoxysilane, p-styryltrimethoxysilane, and p-methoxyphenyltrimethoxysilane; and bifunctional silane such as dimethyldimethoxysilane, dimethyldiethoxysilane, dimethyldiacetoxysilane, di-n-butyldimethoxysilane, and diphenyldimethoxysilane.

Among these silanes, trifunctional silanes are preferably used from the viewpoint of crack resistance and hardness of the cured product. These silanes may be used singly or in a combination of two or more kinds thereof. Also, monofunctional silanes such as trimethylmethoxysilane and tri-n-butylethoxysilane may be used as end-capping agents.

From the viewpoint of improving storage stability, the component (a) includes either or both of an epoxy group-containing repeating structural unit and an oxetane group-containing repeating structural unit, and the total amount of the epoxy group-containing repeating structural unit and the oxetane group-containing repeating structural unit is preferably 1 to 8 mol %, more preferably 3 to 6 mol %, with respect to 100 mol % of the total repeating structural units in the component (a).

Preferred examples of the epoxy group-containing repeating structural unit and the oxetane group-containing repeating structural unit include structures represented by the following general formulas (9) to (11).

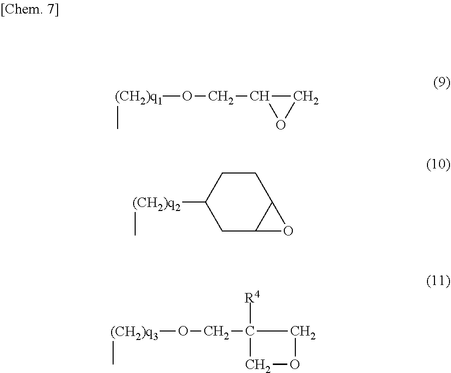

In the above general formulas (9) to (11), q₁ to q₃ are integers of 1 to 5. From the viewpoint of higher sensitivity, q₁ to q₃ are preferably integers of 1 to 3.

In the above general formula (11), R⁴ is hydrogen or a monovalent saturated hydrocarbon group having 1 to 3 carbon atoms. From the viewpoint of higher sensitivity, R⁴ is preferably hydrogen, a methyl group, or an ethyl group.

Specific examples of silane that can be used for synthesis of the component (a) to incorporate these structural units include 3-glycidoxypropyltrimethoxysilane, 3-glycidoxypropyltriethoxysilane, 2-(3,4-epoxycyclohexyl)ethyl trimethoxysilane, (3-ethyl-3-((3-(trimethoxysilyl)propoxy)methyl)oxetane), (oxetane-3-yl)methyltrimethoxysilane, (oxetane-3-yl)methyltriethoxysilane, and (oxetane-3-yl)methyltriacetoxysilane.

Further, from the viewpoint of expecting improvement of a dissolution inhibition effect through π-π stacking with the photosensitizer and achieving higher sensitivity, the (a) polysiloxane includes an aromatic group-containing repeating structural unit, and the (a) polysiloxane includes preferably 60 mol % or more, more preferably 70 mol % or more, and still more preferably 90 mol % or less of the aromatic group-containing repeating structural unit, with respect to 100 mol % of the total repeating structural units constituting the (a) polysiloxane. The proportion of the aromatic group-containing repeating structural unit in terms of the upper limit is not particularly limited, and may be 100 mol %.

Specific examples of the aromatic group-containing repeating structural unit include repeating structural units containing a phenyl group, a tolyl group, a p-styryl group, a p-methoxyphenyl group, a p-hydroxyphenyl group, a 1-(p-hydroxyphenyl)ethyl group, a 2-(p-hydroxyphenyl)ethyl group, a 4-hydroxy-5-(p-hydroxyphenylcarbonyloxy)pentyl group, and a naphthyl group. Specific examples of silane for incorporating the above-described repeating structural unit into (a) polysiloxane include phenyltrimethoxysilane, phenyltriethoxysilane, phenyltripropoxysilane, p-hydroxyphenyltrimethoxysilane, p-hydroxyphenyltriethoxysilane, 2-(p-hydroxyphenyl)trimethoxysilane, 2-(p-hydroxyphenyl)triethoxysilane, 2-(p-hydroxyphenyl)ethyl trimethoxysilane, 2-(p-hydroxyphenyl)ethyl triethoxysilane, naphthyltrimethoxysilane, naphthyltriethoxysilane, p-styryltrimethoxysilane, and p-methoxyphenyltrimethoxysilane.

From the viewpoint of promoting cross-linking between polysiloxanes, three-dimensionally interacting with a photosensitizer, and enhancing the dissolution inhibition effect of the unexposed portion to achieve higher sensitivity, it is preferable that the (a) polysiloxane includes ethylenically unsaturated group-containing repeating structural unit, and the (a) polysiloxane includes the ethylenically unsaturated group-containing repeating structural unit preferably in a range of 10 mol % or more and 70 mol % or less, more preferably 20 mol % or more and 70 mol % or less, with respect to 100 mol % of the total repeating structural units constituting the (a) polysiloxane. When the content of the ethylenically unsaturated group-containing repeating structural unit is 70 mol % or less, generation of residues in an outlined pattern at the time of development can be suppressed. When the content of the ethylenically unsaturated group is 10 mol % or more, sufficient dissolution inhibition effect can be obtained.

Specific examples of the ethylenically unsaturated group-containing repeating structural unit include a vinyl group, a methacrylic group, and an acrylic group. In order to incorporate the above-described repeating structural units into (a) polysiloxane, for example, the following silanes may be polymerized. Examples of the ethylenically unsaturated group-containing silane include vinyltrimethoxysilane, vinyltriethoxysilane, 3-methacryloxypropyltrimethoxysilane, 3-methacryloxypropyltriethoxysilane, and 3-acryloxypropyltrimethoxysilane, and vinyltrimethoxysilane, vinyltriethoxysilane, and 3-acryloxypropyltrimethoxysilane are preferred.

Particularly, from the viewpoint of three-dimensionally interacting with the photosensitizer and further improving the dissolution inhibition effect through π-π stacking with the photosensitizer to achieve higher sensitivity, (a) polysiloxane preferably has a styryl group-containing repeating structural unit, and the (a) polysiloxane includes the styryl group-containing repeating structural unit preferably in a range of 10 mol % or more and 70 mol % or less, more preferably 30 mol % or more and 70 mol % or less, with respect to 100 mol % of the total repeating structural units constituting the (a) polysiloxane. When the content of the styryl group-containing repeating structural unit is 70 mol % or less, generation of residues in an outlined pattern at the time of development can be suppressed. When the content of the styryl group-containing repeating structural unit is 10 mol % or more, sufficient dissolution inhibition effect can be obtained.

Specific examples of the partial structure containing the styryl group in the styryl group-containing repeating structural unit include a 4-vinylphenyl group (p-styryl group), a 3-vinylphenyl group (m-styryl group), a 2-vinylphenyl group (0-styryl group), and 4-vinylphenylmethylene group.

Specific examples of silane for incorporating the styryl group-containing repeating structural unit into (a) polysiloxane by polymerization include styryltrimethoxysilane, styryltriethoxysilane, styryltri(methoxyethoxy)silane, styryltri(propoxy)silane, styryltri(butoxy)silane, styrylmethyldimethoxysilane, styrylethyldimethoxysilane, styrylmethyldiethoxysilane, and styrylmethyldi(methoxyethoxy)silane, and styryltrimethoxysilane, styryltriethoxysilane, styrylmethyldimethoxysilane, and styrylethyldimethoxysilane are preferred.

Note that in a case where one repeating unit contains two or more of the “aromatic group”, the “ethylenically unsaturated group”, the “styryl group”, the “epoxy group”, the “oxetane group”, and a “dicarboxylic acid group” described below, in the component (a), when a certain structural unit corresponds to a structural unit containing each of the above-described groups, the amount of the structural unit with respect to 100 mol % of the total repeating structural units in the component (a) is independently counted as a structural unit corresponding to the structural unit containing that group. For example, a styryl group-containing structural unit is counted as an aromatic group-containing structural unit, an ethylenically unsaturated group-containing structural unit, and a styryl group-containing structural unit.

From the viewpoint of increasing the dissolution rate of the polysiloxane and achieving still higher sensitivity, the (a) polysiloxane includes a dicarboxylic acid group-containing repeating structural unit, and the amount of the dicarboxylic acid group-containing repeating structural unit with respect to 100 mol % of the total repeating structural units in the component (a) is preferably 1 mol % or more, more preferably 1.5 mol % or more, and still more preferably 20 mol % or less, most preferably 7 mol % or less.

The term “dicarboxylic acid group” used herein refers to a partial structure in which a carboxyl group is bonded to each of the two adjacent carbon atoms, and for example, structures illustrated below. The bond between the two adjacent carbon atoms may be, for example, a single bond, a double bond, or a part of an aromatic ring.

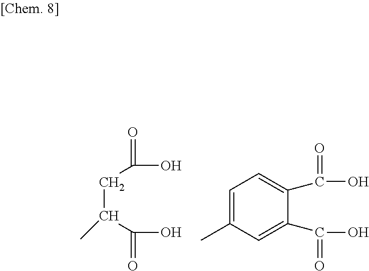

Specific examples of silane for incorporating the dicarboxylic acid group-containing repeating structural unit into (a) polysiloxane by polymerization include 3-trimethoxysilylpropyl succinic anhydride, 3-triethoxysilylpropyl succinic anhydride, 3-triphenoxysilylpropyl succinic anhydride, 3-trimethoxysilylpropyl phthalic anhydride, and 3-trimethoxysilylpropyl cyclohexyl dicarboxylic anhydride. Preferably, 3-trimethoxysilylpropyl succinic anhydride, 3-triethoxysilylpropyl succinic anhydride, and the like. These acid anhydrides undergo ring opening during polymerization, making it possible to easily incorporate the dicarboxylic acid group into polysiloxane.

Further, the weight average molecular weight (Mw) of (a) polysiloxane used in the present invention is not particularly limited, but is preferably 1,000 to 100,000, more preferably 2,000 to 50,000, in terms of polystyrene conversion as measured by GPC (gel permeation chromatography). Mw of less than 1,000 results in poor coating properties, and Mw of more than 100,000 results in poor solubility in a developer during pattern formation.
(a) Polysiloxane in the present invention can be obtained by hydrolysis and partial condensation of the silane mentioned above. The hydrolysis and partial condensation can be carried out using the general methods. For example, a solvent, water, and, as required, a catalyst are added to the mixture, and the mixture is heated and stirred. During stirring, hydrolysis by-products (alcohol such as methanol) and condensation by-products (water) may be removed by distillation, as necessary.

The above-described reaction solvent is not particularly limited, but a solvent similar to that usually used in the composition is used. The addition amount of the solvent is preferably 10 wt % to 1,000 wt % with respect to 100 wt % of silane or of the total amount of silane and silica particles. The addition amount of water used in the hydrolysis reaction is preferably 0.5 to 2 moles per 1 mole of hydrolyzable group.

There is no particular restriction on the catalyst that is added as necessary, but an acid catalyst or a base catalyst is preferably used. Specific examples of the acid catalyst include hydrochloric acid, nitric acid, sulfuric acid, hydrofluoric acid, phosphoric acid, acetic acid, trifluoroacetic acid, formic acid, polycarboxylic acid, or anhydride thereof, and ion exchange resins. Specific examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, amino group-containing alkoxysilane, and ion exchange resins. The addition amount of the catalyst is preferably 0.01 wt % to 10 wt % with respect to 100 wt % of silane.

From the viewpoint of coating properties and storage stability, it is preferable that the polysiloxane solution after hydrolysis and partial condensation contain no by-products such as alcohol and water, and catalysts. They may be removed as necessary. The removal method is not particularly limited. Preferably, a method in which a polysiloxane solution is diluted with an appropriate hydrophobic solvent, then washed with water several times, and the resulting organic layer is concentrated with an evaporator can be used as a method of removing alcohol and water. In addition, a method of treatment with an ion exchange resin, alone or combined with the above-described washing with water, can be used as a method of removing a catalyst.

The positive photosensitive resin composition of the present invention contains (b) a naphthoquinone diazide compound (component (b)) represented by the formula (1).

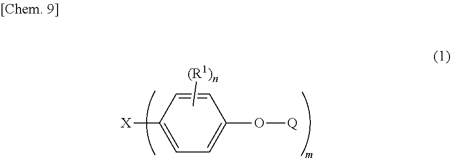

(in the formula (1), R¹ is an alkyl group having 1 to 8 carbon atoms; Q is a naphthoquinone diazide sulfonyl group represented by a structure shown below or a hydrogen atom; at least one of all Qs in the formula (1) is a naphthoquinone diazide sulfonyl group; n is an integer of 0 to 4; m is an integer of 4 to 8; and X is a tetravalent to octavalent organic group having 4 to 30 carbon atoms).

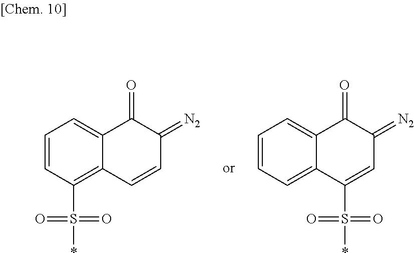

(in the above structure, * represents a binding site).

The component (b) has a structure represented by the formula (1). Since the component (b) has at least one naphthoquinone diazide sulfonyl group in the formula (1), the component (b) interacts with the silanol group of (a) polysiloxane, making it possible to improve the dissolution inhibition effect in the unexposed portion. As a result, the difference in solubility between the unexposed portion and the exposed portion becomes larger, enabling pattern processing with higher sensitivity and higher residual film thickness ratio. In addition, interaction with a Si—OH group in the polysiloxane is effective in inhibiting the condensation of the silanol group, suppressing changes in molecular weight, and improving storage stability.

The naphthoquinone diazide sulfonyl group of Q in the formula (1) represents a basic skeleton, and is allowed to have a substituent, for example, a saturated aliphatic group having 1 to 2 carbon atoms such as a methyl group, an ethyl group, a methoxy group, which does not inhibit development of alkali solubility in the composition after exposure and does not inhibit the interaction with the component (a).

In the formula (1), R¹ is an alkyl group having 1 to 8 carbon atoms. When R¹ has an alkyl group having 1 to 8 carbon atoms, an appropriate hydrophilicity is obtained, and solubility of the exposed portion in the alkaline developer is improved, thereby improving sensitivity. From the viewpoint of further improving sensitivity, R¹ is preferably an alkyl group having 1 to 3 carbon atoms. From the viewpoint of even further improving sensitivity, it is preferable that, in the formula (1), the n be 1 or 2, and R¹ be bonded at ortho position with respect to —OQ group.

In addition, from the viewpoint of improving storage stability, it is preferable that an average esterification ratio of the component (b) be 75% or more, that is, 75 mol % or more of Q be a naphthoquinone diazide sulfonyl group, where all Qs in the formula (1) included in the component (b) is taken as 100 mol %.

Further, in the above formula (1), from the viewpoint of achieving higher sensitivity by improving the dissolution inhibition effect and of improving storage stability, m is preferably 4 to 6, more preferably 4.

Preferred specific examples of the component (b) that satisfies these requirements include the following.

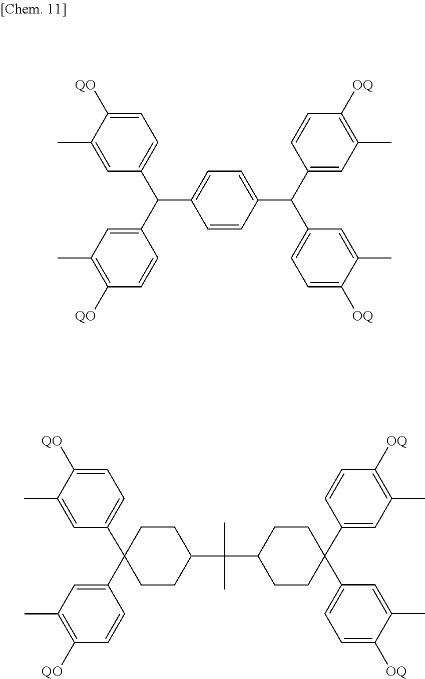

In the compound represented by the above structure, 75 mol % or more of Qs are groups represented by the following formula, and the rest of Qs are hydrogen atoms.

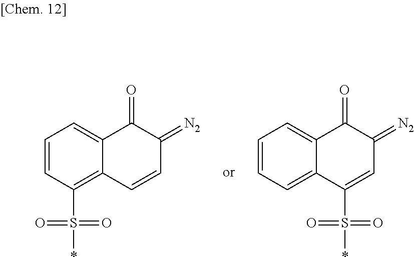

(in the above structure, * represents a binding site).

Further, from the viewpoint of achieving higher sensitivity by improving the dissolution inhibition effect and of improving storage stability, it is more preferable for the X in the formula (1) to include an alicyclic structure.

In the positive photosensitive resin composition of the present invention, the content of the component (b) is not particularly limited, but is preferably 1 to 85 parts by weight, more preferably 1 to 60 parts by weight, still more preferably 1 to 30 parts by weight with respect to 100 parts by weight of the component (a). When the content of the component (b) is 1 part by weight or more, the residual film thickness ratio in the unexposed portion becomes higher. On the other hand, when the content of the component (b) is 85 parts by weight or less, the light transmittance of the cured product can be maintained at a high level.

Particularly, when the component (a) includes a dicarboxylic acid group-containing repeating structural unit, from the viewpoint of achieving higher sensitivity, a ratio M1/M2 is preferably 0.2 to 2.5, more preferably 0.5 to 2.5, where M1 (mol) is a mole number of the dicarboxylic acid group contained in the component (a), and M2 (mol) is a mole number of the naphthoquinone diazide group contained in the component (b).

The values of M1 and M2 can be calculated from the compounding amount of the silane compound for synthesizing the component (a) and the compounding amount of the component (a) solution and the component (b) for preparing the positive photosensitive resin composition. For example, for a positive photosensitive resin composition containing Z5 (g) of a solution (the solid weight of the polysiloxane corresponds to Z5×T2/100 (g)) taken from a polysiloxane solution (total weight, Z4 (g); solid content, T2(%)) synthesized by adding Z1, Z2, and Z3 moles of methyltrimethoxysilane, phenyltrimethoxysilane, and 3-trimethoxysilylpropyl succinic anhydride, respectively, in which the ring opening ratio of 3-trimethoxysilylpropyl succinic anhydride is T1(%), and Y (g) of the naphthoquinone diazide compound of the general formula (1), where m=4, having a proportion of the naphthoquinone diazide sulfonyl group in Q of T3 (mol %) and a molecular weight of M:

$$M 1 = Z 3 \times T 1 / 100 \times Z 5 / Z 4$$

$$M 2 = Y / M \times m \times T 3 / 100$$

Specifically, for a positive photosensitive resin composition containing 10 g of solution taken from a polysiloxane solution with total solution weight of 406 g, solid content of 52 wt %, and the ring opening ratio of the succinic anhydride structure of 95%, which has been synthesized by adding 0.672 moles of methyltrimethoxysilane, 0.672 moles of phenyltrimethoxysilane and 0.336 moles of 3-trimethoxysilyl succinic anhydride in a solvent, and 0.5 g of the naphthoquinone diazide compound (molecular weight, 1328.5) having the structure shown below:

$$M 1 = 0.336 \times 95 / 100 \times 10 / 406 = 0 \text{.00786}$$

$$M 2 = 0.5 / 132 \; 8.5 \times 4 \times 75 / 100 = 0.00 \; 113$$

$$M 1 / M 2 = 6.96$$

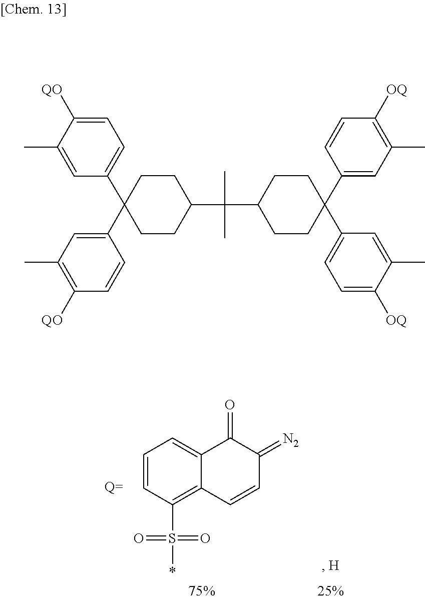

The cured product of the present invention will now be described. The cured product of the present invention is a cured product obtained by heat treatment of the photosensitive resin composition of the present invention.

A method of forming the cured product using the positive photosensitive composition of the present invention will now be described with reference to the specific examples. The positive photosensitive composition of the present invention is applied onto a substrate such as a glass substrate, a SiO substrate, a SiN substrate, or an ITO substrate by a known method such as spinner, dipping or slit coating, and then prebaked with a heating device such as a hot plate or an oven. Preferably, prebaking is performed at a temperature in a range of 50 to 150° C. for 30 seconds to 30 minutes, and the film thickness after prebaking is 0.1 to 15 μm.

After prebaking, patterning exposure is performed at 10 to 200 mJ/cm² (exposure amount conversion at a wavelength of 405 nm) using an uv-visible exposure equipment such as a stepper, a mirror projection mask aligner (MPA), and a parallel light mask aligner (PLA) through a desired mask.

After patterning exposure, the exposed portion is dissolved by development to obtain a pattern. The developing method is preferably immersion in the developer for 5 seconds to 10 minutes by a method such as shower, dipping, or puddle. A known alkaline developer can be used as the developer. Specific examples include aqueous solutions containing one or two or more of inorganic alkali such as alkali metal hydroxide, carbonate, phosphate, silicate, and borate; amines such as 2-diethylaminoethanol, monoethanolamine, and diethanolamine; and quaternary ammonium salts such as TMAH (tetramethyl ammonium hydroxide) and choline. Among them, an aqueous solution of TMAH is preferably used, which is an organic alkali free from the risk of incorporation of metal ion and is also a strong alkali. In general, the aqueous solution of TMAH is preferably used at a concentration of 0.20 to 2.38 wt % from the viewpoint of the solubility of a phenolic hydroxyl group, a silanol group, and a carboxyl group in alkali.

The development is preferably followed by rinse with water. Subsequently dry baking may be performed at a temperature in a range of 50 to 150° C.

Next, this film is thermally cured for about one hour at a temperature in a range of 150 to 300° C. using a heating device such as a hot plate or an oven. The resolution is preferably 10 μm or less. The cured product of the present invention can be applied to a planarization film for TFT in a display device, an inter-layer dielectric film in a semiconductor device, or a core or clad material in an optical waveguide.

The display device of the present invention is a display device, including: a first electrode formed on a substrate, an insulating layer formed on the first electrode so as to partially expose the first electrode, and a second electrode provided opposed to the first electrode, wherein the insulating layer includes the above-mentioned cured product. Particularly, the above-described display device is preferably a display device including a planarization film provided so as to cover bumps and dips on a substrate having a thin film transistor (TFT) formed thereon.

### EXAMPLES

The present invention will be described below using examples, but the aspects of the present invention are not limited to these examples. The following is a list of compounds used in the examples, etc., for which abbreviations are used.
DAA: Diacetone alcohol
PGME: Propylene glycol monomethyl ether

Further, the solid content of the polysiloxane solution and the ring opening ratio of succinic acid were obtained as follows.

### (1) Measurement of Solid Content of Polysiloxane Solution

One gram of a polysiloxane solution was weighed in an aluminum cup, and heated at 250° C. for 30 minutes using a hot plate to evaporate the liquid. The solid remaining in the aluminum cup after heating was weighed to determine the solid content of the polysiloxane solution.

### (2) Ring Opening Ratio of Succinic Acid

The ring opening ratio of succinic acid was determined by measuring the ¹H-NMR of the polysiloxane solution.

### Synthesis Example 1 Synthesis of Polysiloxane (PS-1) Solution

In a 1,000 ml three-neck flask, 91.53 g (0.672 mol) of methyltrimethoxysilane, 166.57 g (0.840 mol) of phenyltrimethoxysilane, 41.40 g (0.168 mol) of 2-(3,4-epoxycyclohexyl)ethyl trimethoxysilane, and 183.57 g of DAA were charged, and an aqueous phosphoric acid solution prepared by dissolving 0.599 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-1) solution. During heating and stirring, dry nitrogen was flowed at 0.070 liters/min. During the reaction, a total of 203 g of by-products, methanol and water, were distilled off. The solid content of the resulting polysiloxane (PS-1) solution was 52 wt %.

### Synthesis Example 2 Synthesis of Polysiloxane (PS-2) Solution

In a 1,000 ml three-neck flask, 68.64 g (0.504 mol) of methyltrimethoxysilane, 199.89 g (1.01 mol) of phenyltrimethoxysilane, 41.40 g (0.168 mol) of 2-(3,4-epoxycyclohexyl)ethyl trimethoxysilane, and 194.01 g of DAA were charged, and an aqueous phosphoric acid solution prepared by dissolving 0.620 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-2) solution. During heating and stirring, dry nitrogen was flowed at 0.070 liters/min. During the reaction, a total of 197 g of by-products, methanol and water, were distilled off. The solid content of the resulting polysiloxane (PS-2) solution was 53 wt %.

### Synthesis Example 3 Synthesis of Polysiloxane (PS-3) Solution

In a 1,000 ml three-neck flask, 68.64 g (0.504 mol) of methyltrimethoxysilane, 99.94 g (0.504 mol) of phenyltrimethoxysilane, 113.1 g (0.504 mol) of p-styryltrimethoxysilane, 41.40 g (0.168 mol) of 2-(3,4-epoxycyclohexyl)ethyl trimethoxysilane, 0.5652 g (2.57×10⁻³ mol) of dibutylhydroxytoluene, and 207.11 g of DAA were charged, and an aqueous phosphoric acid solution prepared by dissolving 0.323 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-3) solution. During heating and stirring, air was flowed at 0.070 liters/min. During the reaction, a total of 208.1 g of by-products, methanol and water, were distilled off. The solid content of the resulting polysiloxane (PS-3) solution was 50 wt %.

### Synthesis Example 4 Synthesis of Polysiloxane (PS-4) Solution

In a 1,000 ml three-neck flask, 86.95 g (0.638 mol) of methyltrimethoxysilane, 99.94 g (0.504 mol) of phenyltrimethoxysilane, 113.1 g (0.504 mol) of p-styryltrimethoxysilane, 8.81 g (0.0336 mol) of 3-trimethoxysilyl succinic anhydride, 0.5652 g (2.57×10⁻³ mol) of dibutylhydroxytoluene, and 193.44 g of DAA were charged, and an aqueous phosphoric acid solution prepared by dissolving 0.309 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-4) solution. During heating and stirring, air was flowed at 0.070 liters/min. During the reaction, a total of 188.89 g of by-products, methanol and water, were distilled off. The resulting polysiloxane (PS-4) solution had the ring opening ratio of the succinic anhydride structure of 95%, the total solution weight of 404.94 g, and the solid content of 52 wt %.

### Synthesis Example 5 Synthesis of Polysiloxane (PS-5) Solution

In a 1,000 ml three-neck flask, 114.42 g (0.840 mol) of methyltrimethoxysilane, 166.56 g (0.840 mol) of phenyltrimethoxysilane, and 171.42 g of DAA were charged, and an aqueous phosphoric acid solution prepared by dissolving 0.556 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-5) solution. During heating and stirring, dry nitrogen was flowed at 0.070 liters/min. During the reaction, a total of 199 g of by-products, methanol and water, were distilled off. The solid content of the resulting polysiloxane (PS-5) solution was 52 wt %.

### Synthesis Example 6 Synthesis of Polysiloxane (PS-6) Solution

In a 1,000 ml three-neck flask, 109.85 g (0.806 mol) of methyltrimethoxysilane, 166.57 g (0.840 mol) of phenyltrimethoxysilane, 8.28 g (0.0336 mol) of 2-(3,4-epoxycyclohexyl)ethyl trimethoxysilane, and 174.10 g of DAA were charged, and an aqueous phosphoric acid solution prepared by dissolving 0.564 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-6) solution. During heating and stirring, dry nitrogen was flowed at 0.070 liters/min. During the reaction, a total of 200 g of by-products, methanol and water, were distilled off. The solid content of the resulting polysiloxane (PS-6) solution was 52 wt %.

### Synthesis Example 7 Synthesis of Polysiloxane (PS-7) Solution

In a 1,000 ml three-neck flask, 96.12 g (0.706 mol) of methyltrimethoxysilane, 166.57 g (0.840 mol) of phenyltrimethoxysilane, 33.11 g (0.134 mol) of 2-(3,4-epoxycyclohexyl)ethyl trimethoxysilane, and 187.11 g of DAA were charged, and an aqueous phosphoric acid solution prepared by dissolving 0.607 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-7) solution. During heating and stirring, dry nitrogen was flowed at 0.070 liters/min. During the reaction, a total of 198 g of by-products, methanol and water, were distilled off. The solid content of the resulting polysiloxane (PS-7) solution was 52 wt %.

### Synthesis Example 8 Synthesis of Polysiloxane (PS-8) Solution

In a 1,000 ml three-neck flask, 80.10 g (0.588 mol) of methyltrimethoxysilane, 199.88 g (1.008 mol) of phenyltrimethoxysilane, 20.70 g (0.084 mol) of 2-(3,4-epoxycyclohexyl)ethyl trimethoxysilane, and 186.99 g of DAA were charged, and an aqueous phosphoric acid solution prepared by dissolving 0.606 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-8) solution. During heating and stirring, dry nitrogen was flowed at 0.070 liters/min. During the reaction, a total of 203 g of by-products, methanol and water, were distilled off. The solid content of the resulting polysiloxane (PS-8) solution was 52 wt %.

### Synthesis Example 9 Synthesis of Polysiloxane (PS-9) Solution

In a 1,000 ml three-neck flask, 80.10 g (0.588 mol) of methyltrimethoxysilane, 99.94 g (0.504 mol) of phenyltrimethoxysilane, 113.06 g (0.504 mol) of p-styryltrimethoxysilane, 20.70 g (0.084 mol) of 2-(3,4-epoxycyclohexyl)ethyl trimethoxysilane, 0.5652 g (2.57×10⁻³ mol) of dibutylhydroxytoluene, and 189.71 g of DAA were charged, and an aqueous phosphoric acid solution prepared by dissolving 0.309 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-9) solution. During heating and stirring, air was flowed at 0.070 liters/min. During the reaction, a total of 199 g of by-products, methanol and water, were distilled off. The solid content of the resulting polysiloxane (PS-3) solution was 52 wt %.

### Synthesis Example 10 Synthesis of Polysiloxane (PS-10) Solution

In a 1,000 ml three-neck flask, 57.21 g (0.420 mol) of methyltrimethoxysilane, 33.31 g (0.168 mol) of phenyltrimethoxysilane, 226.12 g (1.01 mol) of p-styryltrimethoxysilane, 20.70 g (0.084 mol) of 2-(3,4-epoxycyclohexyl)ethyl trimethoxysilane, 1.130 g (5.14×10⁻³ mol) of dibutylhydroxytoluene, and 213.29 g of DAA were charged, and an aqueous phosphoric acid solution prepared by dissolving 0.348 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-10) solution. During heating and stirring, air was flowed at 0.070 liters/min. During the reaction, a total of 197 g of by-products, methanol and water, were distilled off. The solid content of the resulting polysiloxane (PS-10) solution was 52 wt %.

### Synthesis Example 11 Synthesis of Polysiloxane (PS-11) Solution

In a 1,000 ml three-neck flask, 11.44 g (0.084 mol) of methyltrimethoxysilane, 33.31 g (0.168 mol) of phenyltrimethoxysilane, 301.50 g (1.344 mol) of p-styryltrimethoxysilane, 20.70 g (0.084 mol) of 2-(3,4-epoxycyclohexyl)ethyl trimethoxysilane, 1.507 g (6.85×10⁻³ mol) of dibutylhydroxytoluene, and 236.00 g of DAA were charged, and an aqueous phosphoric acid solution prepared by dissolving 0.385 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-11) solution. During heating and stirring, air was flowed at 0.070 liters/min. During the reaction, a total of 202 g of by-products, methanol and water, were distilled off. The solid content of the resulting polysiloxane (PS-11) solution was 52 wt %.

### Synthesis Example 12 Synthesis of Polysiloxane (PS-12) Solution

In a 1,000 ml three-neck flask, 75.52 g (0.554 mol) of methyltrimethoxysilane, 99.94 g (0.504 mol) of phenyltrimethoxysilane, 113.1 g (0.504 mol) of p-styryltrimethoxysilane, 20.70 g (0.084 mol) of 2-(3,4-epoxycyclohexyl)ethyl trimethoxysilane, 8.81 g (0.0336 mol) of 3-trimethoxysilyl succinic anhydride, 0.5652 g (2.57×10⁻³ mol) of dibutylhydroxytoluene, and 197.77 g of DAA were charged, and an aqueous phosphoric acid solution prepared by dissolving 0.322 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-12) solution. During heating and stirring, air was flowed at 0.070 liters/min. During the reaction, a total of 195.43 g of by-products, methanol and water, were distilled off. The resulting polysiloxane (PS-12) solution had the ring opening ratio of the succinic anhydride structure of 95%, the total solution weight of 412.02 g, and the solid content of 52 wt %.

### Synthesis Example 13 Synthesis of Polysiloxane (PS-13) Solution

In a 1,000 ml three-neck flask, 68.65 g (0.504 mol) of methyltrimethoxysilane, 99.94 g (0.504 mol) of phenyltrimethoxysilane, 113.1 g (0.504 mol) of p-styryltrimethoxysilane, 20.70 g (0.084 mol) of 2-(3,4-epoxycyclohexyl)ethyl trimethoxysilane, 22.04 g (0.084 mol) of 3-trimethoxysilyl succinic anhydride, 0.5652 g (2.57×10⁻³ mol) of dibutylhydroxytoluene, and 205.95 g of DAA were charged, and an aqueous phosphoric acid solution prepared by dissolving 0.336 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-13) solution. During heating and stirring, air was flowed at 0.070 liters/min. During the reaction, a total of 192.95 g of by-products, methanol and water, were distilled off. The resulting polysiloxane (PS-13) solution had the ring opening ratio of the succinic anhydride structure of 95%, the total solution weight of 429.05 g, and the solid content of 52 wt %.

### Synthesis Example 14 Synthesis of Polysiloxane (PS-14) Solution

In a 1,000 ml three-neck flask, 57.21 g (0.420 mol) of methyltrimethoxysilane, 99.94 g (0.504 mol) of phenyltrimethoxysilane, 113.1 g (0.504 mol) of p-styryltrimethoxysilane, 20.70 g (0.084 mol) of 2-(3,4-epoxycyclohexyl)ethyl trimethoxysilane, 44.07 g (0.168 mol) of 3-trimethoxysilyl succinic anhydride, 0.5652 g (2.57×10⁻³ mol) of dibutylhydroxytoluene, and 208.34 g of DAA were charged, and an aqueous phosphoric acid solution prepared by dissolving 0.340 g of phosphoric acid in 90.72 g of water was added thereto at room temperature over 15 minutes with stirring. Thereafter, the flask was immersed in an oil bath at 40° C. and stirred for 30 minutes, and then the oil bath was heated to 120° C. over 30 minutes. One hour after the start of temperature rise, the internal temperature of the solution reached 100° C., and thereafter the solution was heated and stirred for 2 hours (internal temperature: 100 to 110° C.) to obtain a polysiloxane (PS-14) solution. During heating and stirring, air was flowed at 0.070 liters/min. During the reaction, a total of 200.95 g of by-products, methanol and water, were distilled off. The resulting polysiloxane (PS-14) solution had the ring opening ratio of the succinic anhydride structure of 95%, the total solution weight of 434.04 g, and the solid content of 52 wt %.

### Synthesis Example 15 Synthesis of Naphthoquinone Diazide Compound (QD-1)

Under dry nitrogen gas flow, 8.65 g (0.015 mol) of TekP-4HBPA (product name, manufactured by HONSHU CHEMICAL INDUSTRY CO., LTD.) and 10.48 g (0.039 mol) of 5-naphthoquinone diazide sulfonyl chloride were dissolved in 66.5 g of acetone, and brought to room temperature, to which was added dropwise 9.11 g (0.09 mol) of triethylamine mixed with 10 g of acetone so as not to bring the temperature in the system to 35° C. or more. After dripping, the mixture was stirred at 23° C. for 30 minutes. 5.32 g of 35% HCl was added for neutralization. A triethylamine salt was filtered, and a filtrate was poured into water. Thereafter, the precipitate that had been separated out was collected by filtration. This precipitate was dried by a vacuum dryer to obtain a naphthoquinone diazide compound (QD-1) of the following structure:

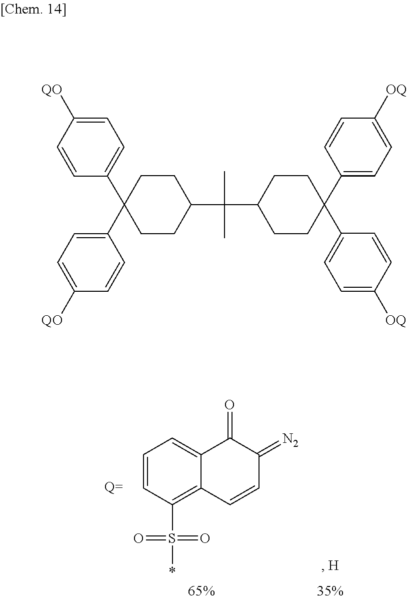

In the above structure, * represents a binding site.

### Synthesis Example 16 Synthesis of Naphthoquinone Diazide Compound (QD-2)

Under dry nitrogen gas flow, 9.49 g (0.015 mol) of TEOC-BOCP (product name, manufactured by ASAHI YUKIZAI CORPORATION) and 10.48 g (0.039 mol) of 5-naphthoquinone diazide sulfonyl chloride were dissolved in 69.9 g of acetone, and brought to room temperature, to which was added dropwise 9.11 g (0.09 mol) of triethylamine mixed with 10 g of acetone so as not to bring the temperature in the system to 35° C. or more. After dripping, the mixture was stirred at 23° C. for 30 minutes. 5.32 g of 35% HCl was added for neutralization. A triethylamine salt was filtered, and a filtrate was poured into water. Thereafter, the precipitate that had been separated out was collected by filtration. This precipitate was dried by a vacuum dryer to obtain a naphthoquinone diazide compound (QD-2) of the following structure:

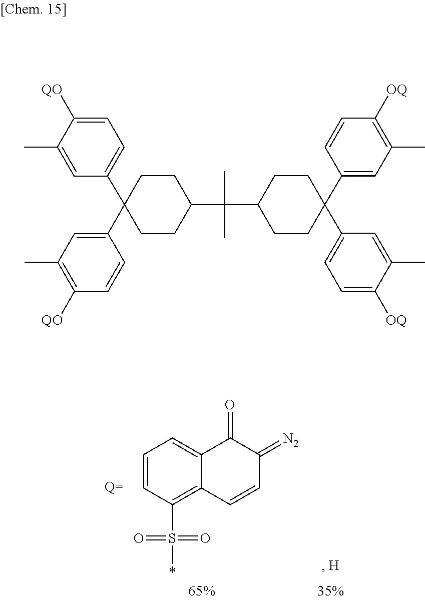

In the above structure, * represents a binding site.

### Synthesis Example 17 Synthesis of Naphthoquinone Diazide Compound (QD-3)

Under dry nitrogen gas flow, 9.49 g (0.015 mol) of TEOC-BOCP (product name, manufactured by ASAHI YUKIZAI CORPORATION) and 12.09 g (0.045 mol) of 5-naphthoquinone diazide sulfonyl chloride were dissolved in 67.3 g of acetone, and brought to room temperature, to which was added dropwise 9.11 g (0.090 mol) of triethylamine mixed with 10 g of acetone so as not to bring the temperature in the system to 35° C. or more. After dripping, the mixture was stirred at 23° C. for 30 minutes. 6.26 g of 35% HCl was added for neutralization. A triethylamine salt was filtered, and a filtrate was poured into water. Thereafter, the precipitate that had been separated out was collected by filtration. This precipitate was dried by a vacuum dryer to obtain a naphthoquinone diazide compound (QD-3) of the following structure:

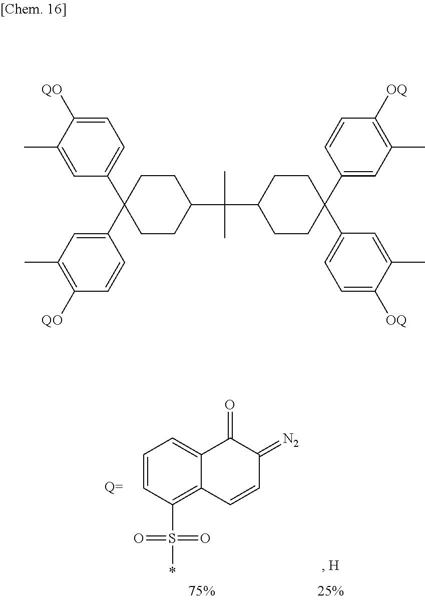

In the above structure, * represents a binding site.

### Synthesis Example 18 Synthesis of Naphthoquinone Diazide Compound (QD-4)

Under dry nitrogen gas flow, 15.32 g (0.05 mol) of TrisP-HAP (product name, manufactured by HONSHU CHEMICAL INDUSTRY CO., LTD.) and 23.11 g (0.086 mol) of 5-naphthoquinone diazide sulfonyl chloride were dissolved in 450 g of 1,4-dioxane, and brought to room temperature, to which was added dropwise 11.13 g (0.11 mol) of triethylamine mixed with 50 g of 1,4-dioxane so as not to bring the temperature in the system to 35° C. or more. After dripping, the mixture was stirred at 30° C. for 2 hours. A triethylamine salt was filtered off, and a filtrate was poured into water. Thereafter, the precipitate that had been separated out was collected by filtration. This precipitate was dried by a vacuum dryer to obtain a naphthoquinone diazide compound (QD-4) of the following structure:

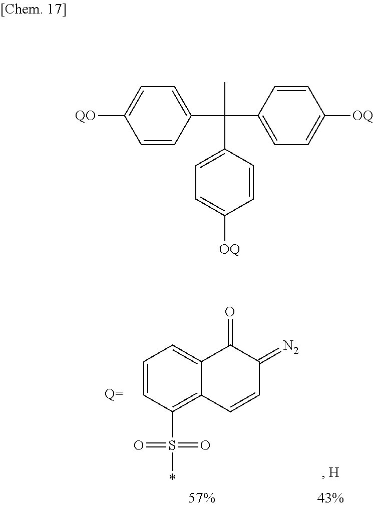

In the above structure, * represents a binding site.

### Synthesis Example 19 Synthesis of Naphthoquinone Diazide Compound (QD-5)

Under dry nitrogen gas flow, 21.23 g (0.05 mol) of TrisP-PA (product name, manufactured by HONSHU CHEMICAL INDUSTRY CO., LTD.) and 29.56 g (0.11 mol) of 5-naphthoquinone diazide sulfonyl chloride were dissolved in 450 g of 1,4-dioxane, and brought to room temperature, to which was added dropwise 11.13 g (0.11 mol) of triethylamine mixed with 50 g of 1,4-dioxane so as not to bring the temperature in the system to 35° C. or more. After dripping, the mixture was stirred at 30° C. for 2 hours. A triethylamine salt was filtered, and a filtrate was poured into water. Thereafter, the precipitate that had been separated out was collected by filtration. This precipitate was dried by a vacuum dryer to obtain a naphthoquinone diazide compound (QD-5) of the following structure:

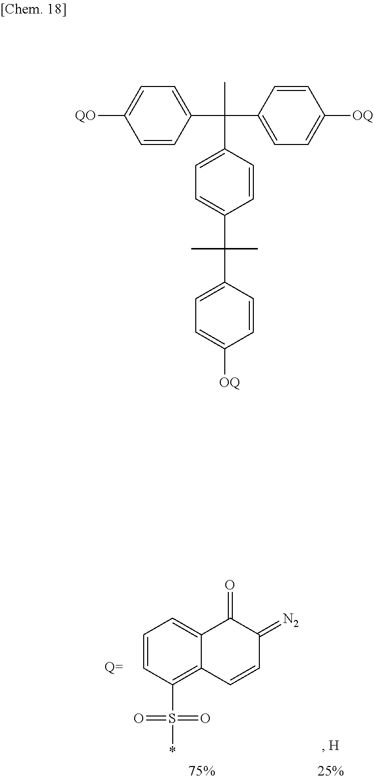

In the above structure, * represents a binding site.

### Example 1

Under a yellow light, 0.671 g (10 parts by weight with respect to 100 parts by weight of polysiloxane solids) of a naphthoquinone diazide compound (QD-1) was dissolved in 4.84 g of DAA and 10.9 g of PGME, and then 12.9 g of a polysiloxane (PS-1) solution was added and stirred. Then, filtration through a 0.45 μm filter was performed to obtain a positive photosensitive composition (PP-1). The prepared positive photosensitive composition (PP-1) was spin-coated on a glass substrate (OA-10, manufactured by Nippon Electric Glass Co., Ltd.) at an arbitrary rotation speed using a spin coater (1H-360S, manufactured by MIKASA CO., LTD.), and then prebaked at 100° C. for 3 minutes using a hot plate (SCW-636, manufactured by Dainippon Screen Mfg. Co., Ltd) to prepare a prebaked film having a film thickness of 1.5 μm. The prepared prebaked film was irradiated at 200, 300, and 400 mJ/cm² (exposure amount conversion at a wavelength of 405 nm) using a parallel light mask aligner (PLA-501F, manufactured by Canon Inc., hereinafter referred to as PLA) and a gray scale mask. A grayscale mask is a mask under which gradual exposure from 1% to 100% can be attained all at once when irradiated from above the mask. Thereafter, the film was shower-developed with 2.38 wt % of TMAH aqueous solution for 90 seconds using an automatic developing apparatus (AD-2000, manufactured by TAKIZAWA SANGYO K.K.), and then rinsed with water for 30 seconds. Next, using PLA, the entire surface of the film was exposed to an ultra-high pressure mercury lamp at 200, 300, and 400 mJ/cm² (exposure amount conversion at a wavelength of 405 nm). Thereafter, a cured product was produced by curing in an air at 230° C. for an hour using an oven (IHPS-222, manufactured by ESPEC CORP.).

The following measurements were carried out on this cured product.

### (1) Film Thickness Measurement

The thicknesses of the prebaked film and the cured product were measured using a Lambda Ace STM-602 manufactured by Dainippon Screen Mfg. Co., Ltd. at a refractive index of 1.55.

### (2) Residual Film Thickness Ratio

The composition is applied onto a glass substrate, prebaked on a hot plate at 100° C. for 180 seconds, and then developed. The residual film thickness ratio is calculated as follows:

Residual film thickness ratio (%)=(ii)×100/(i)

where (i) (μm) is a film thickness after prebaking and (ii) (μm) is a film thickness of the unexposed portion after development.

### (3) Sensitivity

The film is shower-developed with 2.38 wt % of TMAH aqueous solution for 90 seconds, rinsed with water for 30 seconds, and then the patterned film is baked in an oven at 230° C. for an hour. After baking, the exposure amount at which a 20 μm line-and-space pattern is resolved at a 1:1 width (hereinafter referred to as the optimum exposure amount) is determined as the sensitivity.

### (4) Storage Stability

A positive photosensitive composition was prepared, and the initial sensitivity (Eop (0)) was measured, and then the composition was stored in an incubator (Cool Incubator KMH-050 (AS ONE Corporation)) at 25° C. for 3 days. Thereafter, the sensitivity (Eop (3)) was measured again to evaluate the storage stability of the composition. Sensitivity change x (%) was calculated using the following formula, and the evaluation criteria were defined as follows.

$$Sensitivity change x ( \% ) = Eop ( 3 ) / Eop ( 0 ) \times 100$$

A: 120≥x
B: 150≥x>120
C: x>150

In the above-described measurement, a sample having an initial sensitivity (Eop(0)) of 120 mJ/cm² or less and an evaluation of the sensitivity change x equal to or better than B was deemed to be acceptable.

The details of the compositions of Example 1 are given in Table 1 and the evaluation results are given in Table 2.

### Examples 2 to 24, and Comparative Examples 1 and 2

The positive photosensitive compositions (PP-2 to PP-26) were obtained in the same manner as in Example 1, except that polysiloxane (PS-1 to PS-14) solutions and naphthoquinone diazide compounds (QD-1 to QD-5) were added in the addition amounts listed in Table 1. Details of the compositions are also given in Table 1. Using each of the obtained compositions, evaluation of each composition was carried out in the same manner as in Example 1. The results of each evaluation are given in Table 2

TABLE 1

| | | Composition | | | | | | | |
|---|---|---|---|---|---|---|---|---|---|
| | | (a) Polysiloxane | | | | | | | |
| | | | | | | | | Addition | |
| | | | | | | | | amount of | |
| | | Article | Description | Description | Description | Description | Description | solution | M1 |
| | Composition | number | 1 | 2 | 3 | 4 | 5 | (g) | (mol) |
| Example 1 | PP-1 | PS-1 | 50 | 10 | 0 | 0 | 0 | 12.9 | 0 |
| Example 2 | PP-2 | | 50 | 10 | 0 | 0 | 0 | 12.9 | 0 |
| Example 3 | PP-3 | | 50 | 10 | 0 | 0 | 0 | 12.9 | 0 |
| Example 4 | PP-4 | PS-2 | 60 | 10 | 0 | 0 | 0 | 12.9 | 0 |
| Example 5 | PP-5 | PS-3 | 60 | 10 | 30 | 30 | 0 | 12.9 | 0 |
| Example 6 | PP-6 | PS-4 | 60 | 0 | 30 | 30 | 2 | 12.9 | 0.00102 |
| Example 7 | PP-8 | PS-5 | 50 | 0 | 0 | 0 | 0 | 12.9 | 0 |
| Example 8 | PP-9 | PS-6 | 50 | 2 | 0 | 0 | 0 | 12.9 | 0 |
| Example 9 | PP-10 | PS-7 | 50 | 8 | 0 | 0 | 0 | 12.9 | 0 |
| Example 10 | PP-11 | PS-8 | 60 | 5 | 0 | 0 | 0 | 12.9 | 0 |
| Example 11 | PP-12 | PS-9 | 60 | 5 | 30 | 30 | 0 | 12.9 | 0 |
| Example 12 | PP-13 | PS-10 | 70 | 5 | 60 | 60 | 0 | 12.9 | 0 |
| Example 13 | PP-14 | PS-11 | 90 | 5 | 80 | 80 | 0 | 12.9 | 0 |
| Example 14 | PP-15 | | 60 | 5 | 30 | 30 | 2 | 12.9 | 0.00100 |
| Example 15 | PP-16 | PS-12 | 60 | 5 | 30 | 30 | 2 | 12.9 | 0.00100 |
| Example 16 | PP-17 | | 60 | 5 | 30 | 30 | 2 | 12.9 | 0.00100 |
| Example 17 | PP-18 | | 60 | 5 | 30 | 30 | 2 | 12.9 | 0.00100 |
| Example 18 | PP-19 | | 60 | 5 | 30 | 30 | 2 | 12.9 | 0.00100 |
| Example 19 | PP-20 | PS-13 | 60 | 5 | 30 | 30 | 5 | 12.9 | 0.00240 |
| Example 20 | PP-21 | | 60 | 5 | 30 | 30 | 5 | 12.9 | 0.00240 |
| Example 21 | PP-22 | | 60 | 5 | 30 | 30 | 5 | 12.9 | 0.00240 |
| Example 22 | PP-23 | | 60 | 5 | 30 | 30 | 5 | 12.9 | 0.00240 |
| Example 23 | PP-24 | | 60 | 5 | 30 | 30 | 5 | 12.9 | 0.00240 |
| Example 24 | PP-25 | PS-14 | 60 | 5 | 30 | 30 | 10 | 12.9 | 0.00474 |
| Comparative | PP-7 | PS-1 | 50 | 10 | 0 | 0 | 0 | 12.9 | 0 |
| Example 1 | | | | | | | | | |
| Comparative | PP-26 | PS-5 | 50 | 0 | 0 | 0 | 0 | 12.9 | 0 |
| Example 2 | | | | | | | | | |

TABLE 1

| | | Composition | | | | | | | | | |
|---|---|---|---|---|---|---|---|---|---|---|---|
| | | (b) Quinone diazide compound represented by formula (1) | | | | | | | | | |
| | | | | | | | | Addition | | | |
| | | Article | Value | Value | Description | Description | Structure | amount | Description | M2 | |
| | Composition | number | of n | of m | 6 | 7 | of X | (g) | 8 | (mol) | M1/M2 |
| Example 1 | PP-1 | QD-1 | 0 | 4 | — | 65 | Alicyclic | 0.671 | 10.0 | 0.00148 | 0 |
| Example 2 | PP-2 | QD-2 | 1 | 4 | Ortho | 65 | Alicyclic | 0.671 | 10.0 | 0.00141 | 0 |
| | | | | | position | | | | | | |
| Example 3 | PP-3 | QD-3 | 1 | 4 | Ortho | 75 | Alicyclic | 0.671 | 10.0 | 0.00151 | 0 |
| | | | | | position | | | | | | |
| Example 4 | PP-4 | QD-3 | 1 | 4 | Ortho | 75 | Alicyclic | 0.684 | 10.0 | 0.00154 | 0 |
| | | | | | position | | | | | | |
| Example 5 | PP-5 | QD-3 | 1 | 4 | Ortho | 75 | Alicyclic | 0.645 | 10.0 | 0.00146 | 0 |
| | | | | | position | | | | | | |
| Example 6 | PP-6 | QD-3 | 1 | 4 | Ortho | 75 | Alicyclic | 0.722 | 10.8 | 0.00163 | 0.62 |
| | | | | | position | | | | | | |
| Example 7 | PP-8 | QD-3 | 1 | 4 | Ortho | 75 | Alicyclic | 0.671 | 10.0 | 0.00151 | 0 |
| | | | | | position | | | | | | |
| Example 8 | PP-9 | QD-3 | 1 | 4 | Ortho | 75 | Alicyclic | 0.671 | 10.0 | 0.00151 | 0 |
| | | | | | position | | | | | | |
| Example 9 | PP-10 | QD-3 | 1 | 4 | Ortho | 75 | Alicyclic | 0.671 | 10.0 | 0.00151 | 0 |
| | | | | | position | | | | | | |
| Example 10 | PP-11 | QD-3 | 1 | 4 | Ortho | 75 | Alicyclic | 0.671 | 10.0 | 0.00151 | 0 |
| | | | | | position | | | | | | |
| Example 11 | PP-12 | QD-3 | 1 | 4 | Ortho | 75 | Alicyclic | 0.671 | 10.0 | 0.00151 | 0 |
| | | | | | position | | | | | | |
| Example 12 | PP-13 | QD-3 | 1 | 4 | Ortho | 75 | Alicyclic | 0.671 | 10.0 | 0.00151 | 0 |
| | | | | | position | | | | | | |
| Example 13 | PP-14 | QD-3 | 1 | 4 | Ortho | 75 | Alicyclic | 0.671 | 10.0 | 0.00151 | 0 |
| | | | | | position | | | | | | |
| Example 14 | PP-15 | QD-3 | 1 | 4 | Ortho | 75 | Alicyclic | 0.190 | 2.8 | 0.00043 | 2.33 |
| | | | | | position | | | | | | |
| Example 15 | PP-16 | QD-3 | 1 | 4 | Ortho | 75 | Alicyclic | 0.671 | 10.0 | 0.00151 | 0.66 |
| | | | | | position | | | | | | |
| Example 16 | PP-17 | QD-3 | 1 | 4 | Ortho | 75 | Alicyclic | 1.500 | 22.4 | 0.00339 | 0.30 |
| | | | | | position | | | | | | |
| Example 17 | PP-18 | QD-3 | 1 | 4 | Ortho | 75 | Alicyclic | 2.500 | 37.3 | 0.00565 | 0.18 |
| | | | | | position | | | | | | |
| Example 18 | PP-19 | QD-3 | 1 | 4 | Ortho | 75 | Alicyclic | 0.150 | 2.2 | 0.00034 | 2.95 |
| | | | | | position | | | | | | |
| Example 19 | PP-20 | QD-3 | 1 | 4 | Ortho | 75 | Alicyclic | 0.450 | 6.7 | 0.00102 | 2.36 |
| | | | | | position | | | | | | |
| Example 20 | PP-21 | QD-3 | 1 | 4 | Ortho | 75 | Alicyclic | 1.800 | 26.8 | 0.00406 | 0.59 |
| | | | | | position | | | | | | |
| Example 21 | PP-22 | QD-3 | 1 | 4 | Ortho | 75 | Alicyclic | 4.000 | 59.6 | 0.00903 | 0.27 |
| | | | | | position | | | | | | |
| Example 22 | PP-23 | QD-3 | 1 | 4 | Ortho | 75 | Alicyclic | 0.370 | 5.5 | 0.00084 | 2.87 |
| | | | | | position | | | | | | |
| Example 23 | PP-24 | QD-3 | 1 | 4 | Ortho | 75 | Alicyclic | 5.500 | 82.0 | 0.01242 | 0.19 |
| | | | | | position | | | | | | |
| Example 24 | PP-25 | QD-3 | 1 | 4 | Ortho | 75 | Alicyclic | 0.671 | 10.0 | 0.00151 | 3.13 |
| | | | | | position | | | | | | |
| Comparative | PP-7 | QD-4 | 0 | 3 | — | 57 | Non- | 0.671 | 10.0 | 0.00163 | 0 |
| Example 1 | | | | | | | alicyclic | | | | |
| Comparative | PP-26 | QD-5 | 0 | 3 | — | 75 | Non- | 0.671 | 10.0 | 0.00159 | 0 |
| Example 2 | | | | | | | alicyclic | | | | |

In Table 1, the meanings of the terms are as follows:
Description 1: The content (mol %) of the aromatic group-containing repeating structural unit with respect to 100 mol % of the total repeating structural units constituting the component (a)
Description 2: The content (mol %) of the epoxy group-containing repeating structural unit with respect to 100 mol % of the total repeating structural units constituting the component (a).
Description 3: The content (mol %) of the ethylenically unsaturated group-containing repeating structural unit with respect to 100 mol % of the total repeating structural units constituting the component (a).
Description 4: The content (mol %) of the styryl group-containing repeating structural unit with respect to 100 mol % of the total repeating structural units constituting the component (a).
Description 5: The content (mol %) of the dicarboxylic acid group-containing repeating structural unit with respect to 100 mol % of the total repeating structural units constituting the component (a).
Description 6: The binding site of R¹ with respect to-OQ group.
Description 7: The content (mol %) of the naphthoquinone diazide sulfonyl group where all Qs in the formula (1) included in the component (b) is taken as 100 mol %.
Description 8: The content (parts by weight) with respect to 100 parts by weight of the component (a).

TABLE 2

| | | Photosensitive properties | | | | | |
|---|---|---|---|---|---|---|---|
| | | Day 0 | | Day 3 | | Storage stability | |
| | | Residual film | Sensitivity/ | Residual film | Sensitivity/ | Eop(3)/Eop(0) × | |
| | | thickness ratio | Eop(0) | thickness ratio | Eop(3) | 100 | |
| | Composition | (%) | (mJ/cm²) | (%) | (mJ/cm²) | (%) | Evaluation |
| Example 1 | PP-1 | 88 | 120 | 94 | 168 | 140 | B |
| Example 2 | PP-2 | 89 | 112 | 94 | 148 | 132 | B |
| Example 3 | PP-3 | 94 | 105 | 96 | 124 | 118 | A |
| Example 4 | PP-8 | 94 | 106 | 96 | 126 | 119 | A |
| Example 5 | PP-9 | 94 | 105 | 96 | 113 | 108 | A |
| Example 6 | PP-10 | 94 | 105 | 96 | 113 | 108 | A |
| Example 7 | PP-4 | 95 | 96 | 97 | 115 | 120 | A |
| Example 8 | PP-11 | 95 | 97 | 95 | 101 | 104 | A |
| Example 9 | PP-5 | 95 | 70 | 95 | 81 | 115 | A |
| Example 10 | PP-12 | 95 | 70 | 95 | 73 | 104 | A |
| Example 11 | PP-13 | 95 | 71 | 95 | 74 | 104 | A |
| Example 12 | PP-14 | 95 | 97 | 95 | 101 | 104 | A |
| Example 13 | PP-6 | 95 | 56 | 96 | 64 | 114 | A |
| Example 14 | PP-15 | 96 | 56 | 96 | 58 | 104 | A |
| Example 15 | PP-16 | 96 | 55 | 96 | 57 | 104 | A |
| Example 16 | PP-17 | 96 | 61 | 96 | 63 | 104 | A |
| Example 17 | PP-18 | 95 | 64 | 96 | 67 | 104 | A |
| Example 18 | PP-19 | 95 | 64 | 96 | 67 | 104 | A |
| Example 19 | PP-20 | 96 | 56 | 96 | 58 | 104 | A |
| Example 20 | PP-21 | 96 | 56 | 96 | 58 | 104 | A |
| Example 21 | PP-22 | 96 | 61 | 96 | 63 | 104 | A |
| Example 22 | PP-23 | 95 | 64 | 96 | 67 | 104 | A |
| Example 23 | PP-24 | 95 | 64 | 96 | 67 | 104 | A |
| Example 24 | PP-25 | 95 | 68 | 96 | 71 | 104 | A |
| Comparative | PP-7 | 78 | 128 | 88 | 196 | 153 | C |
| Example 1 | | | | | | | |
| Comparative | PP-26 | 77 | 135 | 87 | 230 | 170 | C |
| Example 2 | | | | | | | |

1. A positive photosensitive resin composition comprising:
(a) polysiloxane (hereinafter referred to as “component (a)”), and
(b) a naphthoquinone diazide compound represented by formula (1) (hereinafter referred to as “component (b)”): 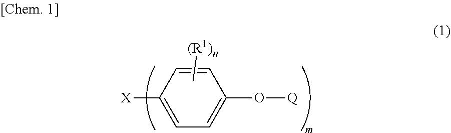
(in the formula (1), R¹ is an alkyl group having 1 to 8 carbon atoms;
Q is a naphthoquinone diazide sulfonyl group represented by the structure shown below or a hydrogen atom, and at least one of all Qs in the formula (1) is a naphthoquinone diazide sulfonyl group:
n is an integer of 0 to 4;
m is an integer of 4 to 8; and
X is a tetravalent to octavalent organic group having 4 to 30 carbon atoms) 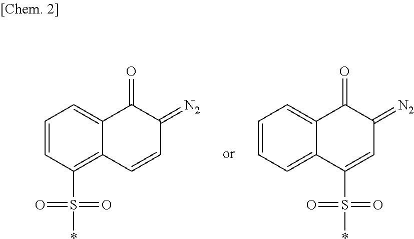
(in the above structure, * represents a binding site).

2. The positive photosensitive resin composition according to claim 1,
wherein the component (b) is represented by the formula (1) in which n is 1 or 2; and R¹ is bonded at ortho position with respect to-OQ group.

3. The positive photosensitive resin composition according to claim 1,
wherein an average esterification ratio of the component (b) is 75% or more.

4. The positive photosensitive resin composition according to claim 1,
wherein the component (b) is represented by the formula (1) in which X includes an alicyclic structure.

5. The positive photosensitive resin composition according to claim 1,
wherein the component (a) includes either or both of an epoxy group-containing repeating structural unit and an oxetane group-containing repeating structural unit; and
the total amount of the epoxy group-containing repeating structural unit and the oxetane group-containing repeating structural unit is 1 to 8 mol % with respect to 100 mol % of the total repeating structural units in the component (a).

6. The positive photosensitive resin composition according to claim 1,
wherein the component (a) includes an aromatic group-containing repeating structural unit, and
in the component (a), the amount of the aromatic group-containing repeating structural unit is 60 mol % or more with respect to 100 mol % of the total repeating structural units of the component (a).

7. The positive photosensitive resin composition according to claim 1,
wherein the component (a) includes an ethylenically unsaturated group-containing repeating structural unit, and
in the component (a), an amount of the ethylenically unsaturated group-containing repeating structural unit is 10 mol % or more and 70 mol % or less with respect to 100 mol % of the total repeating structural units of the component (a).

8. The positive photosensitive resin composition according to claim 6,
wherein the component (a) includes a styryl group-containing repeating structural unit, and
in polysiloxane that is the component (a), an amount of the styryl group-containing repeating structural unit is 10 to 70 mol % with respect to 100 mol % of the total repeating structural units of the component (a).

9. The positive photosensitive resin composition according to claim 1,
wherein the component (a) includes a dicarboxylic acid group-containing repeating structural unit, and
in the component (a), an amount of the dicarboxylic acid group-containing repeating structural unit is 1 mol % or more with respect to 100 mol % of the total repeating structural units of the component (a).

10. The positive photosensitive resin composition according to claim 9,
wherein a ratio M1/M2 is 0.2 to 2.5 where M1 (mol) is a mole number of the dicarboxylic acid group contained in the component (a), and M2 (mol) is a mole number of the naphthoquinone diazide group contained in the component (b).

11. A cured product of the positive photosensitive resin composition according to claim 1 that was subjected to heat treatment.

12. A display device comprising:
a first electrode formed on a substrate;
an insulating layer formed on the first electrode so as to partially expose the first electrode;
a display function section which is provided between the partially exposed first electrode and a second electrode described below and which causes an optical change upon application of a voltage; and
the second electrode provided opposed to the first electrode,
wherein the insulating layer includes the cured product according to claim 11.

13. A display device comprising a planarization film provided so as to cover bumps and dips on a substrate having a thin film transistor (TFT) formed thereon,
wherein the planarization film includes the cured product according to claim 11.
